(19) United States
(12) Patent Application Publication
(10) Pub. No.: US 2006/0166382 A1
(43) Pub. Date: Jul. 27, 2006

(54) Method and apparatus for detecting backside particles during wafer processing

(76) Inventor: Byoung-Hoon Kim, Gyeonggi-do (KR)

Correspondence Address: MARGER JOHNSON & MCCOLLOM, P.C., 210 SW MORRISON STREET, SUITE 400, PORTLAND, OR, 97204, US

(21) Appl. No.: 11/342,228

(22) Filed: Jan. 26, 2006

(30) Foreign Application Priority Data
Jan. 27, 2005 (KR) 2005-07743

(51) Int. Cl. H01L 21/66

(52) U.S. Cl. 438/14; 438/800; 438/906

(57) ABSTRACT

A method and apparatus for detecting backside particles during wafer processing is provided. The method includes holding a wafer with vacuum pressure, detecting the presence of particles on a backside of the wafer while holding the wafer with vacuum pressure, transferring the wafer into a process chamber and performing a wafer processing in the process chamber. The presence of particles may be detected if the vacuum pressure varies out of a predetermined range.

### CROSS-REFERENCE TO RELATED APPLICATION

This application claims the benefit under 35 U.S.C. § 119 of Korean Patent Application No. 10-2005-0007743, filed on Jan. 27, 2005, the entire disclosure of which is hereby incorporated by reference.

### TECHNICAL FIELD

This disclosure relates to processing substrates used in fabricating semiconductor devices or flat panel display devices and, more particularly, to a method and apparatus for detecting backside particles during wafer processing.

### BACKGROUND

As the integration density of semiconductor devices continues to increase, various research aimed at improving the productivity of semiconductor devices continues to progress. To improve the productivity of the semiconductor device, the semiconductor device should have no defects. Defects may occur at various stages of semiconductor device fabrication. Defects on the backside of a wafer may especially linger and affect subsequent processing steps.

Defects on the backside of the wafer result mainly from accumulation of unwanted particles. The particles may be dust, polymer deposits, and/or excess photo-resist accumulated during processing or transferring the wafer. Such accumulation of unwanted particles may cause problems during subsequent processing steps. For example, a photoresist may cling to the backside of the wafer while a photoresist layer is forming on a front side of the wafer. The photoresist on the backside of the wafer adversely affects focusing in a subsequent lithography process and leads a malformed pattern. This may be a major cause of defects in semiconductor devices.

In addition, in a process of forming a thin film on the front side of the wafer by chemical vapor deposition (CVD) or sputtering, backside particles prevent the wafer from mounting properly on a chuck. In such a case, the process should be suspended, which results in considerable downtime. Accordingly, backside particles deteriorate productivity and run up manufacturing costs.

An apparatus for detecting backside particles is disclosed in U.S. Pat. No. 5,963,315 entitled “Method and Apparatus for Processing a Semiconductor Wafer On a Robotic Track Having Access To In Situ Wafer Backside Particle Detection” by Hiatt, et al. According to Hiatt, et al., a laser source and a detector are mounted on a robotic arm, or within a semiconductor processing tool. While the wafer is transferred by the robotic arm, its backside is scanned by a laser beam to detect particles.

Another apparatus for detecting backside particles is disclosed in U.S. Pat. No. 6,204,917 entitled “Backside Contamination Inspection Device” by Smedt, et al. According to Smedt, et al., the semiconductor wafer is rotated to an inclined state. The wafer is supported by roller bearings and its backside is scanned by a scan head to detect particles. The scan head includes a laser illuminator and a CCD sensor and moves in close proximity to the surface being scanned to detect particles.

U.S. Pat. No. 6,733,594 B2 entitled “Method and Apparatus for Reducing He Backside Faults During Wafer Processing” by Nguyen discloses cleaning a wafer before introducing it into a process chamber to remove contamination of the backside of the wafer.

Generally, a laser source and a coupled sensor are used to detect backside particles. The laser source emits a laser beam onto a predetermined area of the backside of the wafer and the sensor receives a reflected beam. When particles exist on the backside of the wafer, the incident angle of the reflected beam upon the sensor varies. Backside particles can be detected by measuring the incident angle of the reflected beam. However, the laser source and the sensor should be separately mounted, thereby complicating the apparatus. Also, considerable time is required to scan the whole surface of the wafer using the laser beam, thus delaying the overall wafer process.

### SUMMARY

A method of processing a wafer includes holding the wafer with a vacuum pressure and detecting a presence of a particle on a backside of the wafer while holding the wafer with the vacuum pressure. The wafer is then transferred to a process chamber where wafer processing is performed. The vacuum pressure is measured while the wafer is held, and a particle is detected if a variation in the measured pressure is outside of a predetermined range.

The method may also include ejecting a gas toward the backside of the wafer while holding the wafer with the vacuum pressure. The pressure of the ejected gas is measured and if the pressure is outside of a predetermined range, then a particle is determined to be on the backside of the wafer.

An apparatus for processing a wafer includes a transfer chamber, a load lock chamber connected to the transfer chamber, a process chamber connected to the transfer chamber and a particle detection chamber connected to the transfer chamber. The particle detection chamber includes a wafer receiving plate and a vacuum chuck disposed in the wafer receiving plate to hold the wafer in contact with the plate.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a schematic diagram showing an apparatus for processing wafers;

FIG. 2 is a schematic diagram illustrating a particle detection chamber;

FIGS. 3A to 3C are schematic diagrams illustrating operations of a particle detection chamber;

FIG. 4 is a plan view illustrating an example of a particle detection chamber;

FIG. 5 is a plan view illustrating another example of a particle detection chamber;

FIG. 6 is a flowchart illustrating a method for processing wafers;

FIG. 7 is a flowchart illustrating step 430 of FIG. 6;

FIG. 8 is a schematic diagram showing an apparatus for processing wafers;

FIG. 9 is a schematic perspective view illustrating an aligner; and

FIG. 10 is a flowchart illustrating a method for processing wafers.

### DETAILED DESCRIPTION

Reference will now be made in detail to the embodiments of the present general inventive concept, examples of which are illustrated in the accompanying drawings, wherein like reference numerals refer to the like elements throughout. The embodiments are described below in order to explain the present general inventive concept while referring to the figures.

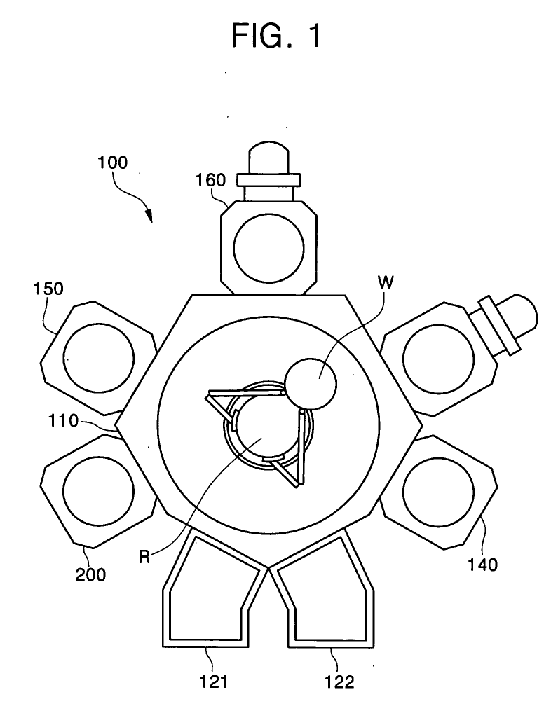

FIG. 1 is a schematic diagram showing an apparatus 100 for processing wafers. Referring to FIG. 1, the apparatus for processing wafers 100 includes a transfer chamber 110, a first load lock chamber 121, a second load lock chamber 122, a process chamber 160 and a particle detection chamber 200.

The transfer chamber 110 transfers a wafer W between the first load lock chamber 121, the second load lock chamber 122, the process chamber 160 and the particle detection chamber 200. A robot R is disposed on the transfer chamber 110 to transfer the wafer W. The robot R may transfer the wafer W from the first load lock chamber 121 to the particle detection chamber 200, from the particle detection chamber 200 to a wafer cleaning chamber 140, from the particle detection chamber 200 to an aligner 150, from the aligner 150 to the process chamber 160, and from the process chamber 160 to the second load lock chamber 122. Also, the robot R may transfer the wafer W between process chambers 160. The transfer chamber 110 and the robot R are generally well known in the art.

The wafer W may include various kinds of substrates, on which layers are formed by etching, deposition, and patterning, as well as semiconductor wafers. The backside of the wafer means the opposite side of a front side of the wafer on which specific layers are formed by etching, deposition, etc., or some pattern is formed.

The first and second load lock chambers 121 and 122 may be connected to the transfer chamber 110. The first load lock chamber 121 provides a space for temporarily storing the wafers W to be loaded into the transfer chamber 110. The second load lock chamber 122 offers a space for temporarily storing the wafers W unloaded from the transfer chamber 110. The first load lock chamber 121 may correspond to an input load lock chamber and the second load lock chamber 122 may correspond to an output load lock chamber. Alternatively, one load lock chamber may be used as both an input load lock chamber and an output load lock chamber. Load lock chambers are generally well known in the art.

The process chamber 160 for performing a predetermined processing on the front side of the wafer W is disposed on the transfer chamber 110. The process may include etching, deposition, or some patterning. The process chamber 160 may be a sputtering apparatus, a spinner, a CVD apparatus, etc.

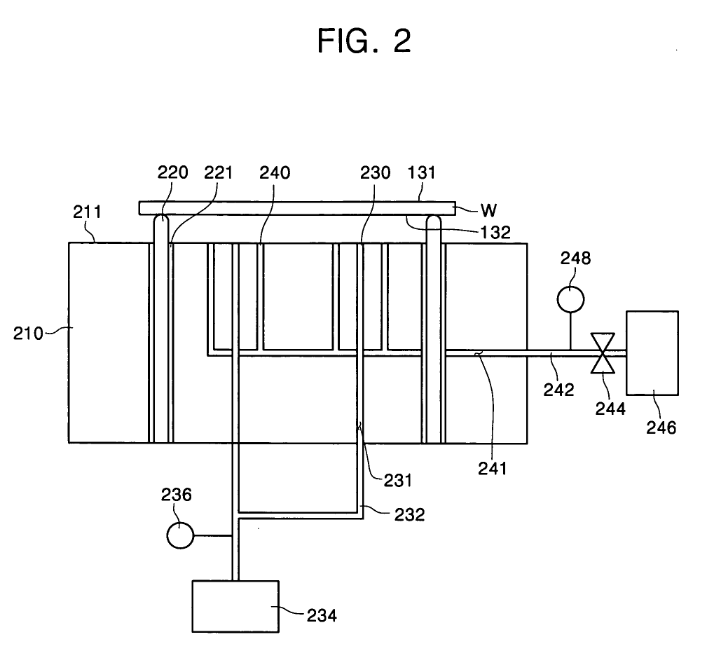

The particle detection chamber 200 is disposed on the transfer chamber 110. FIG. 2 is a schematic diagram illustrating the particle detection chamber 200 of FIG. 1.

Referring to FIG. 2, the particle detection chamber 200 includes a plate 210 for receiving the wafer W, a vacuum chuck 230, and a nozzle 240. A chamber wall (not shown) surrounding the plate 210 may be installed to provide an airtight space.

Support pins 220 onto which the wafer W is temporarily mounted. The support pins 220 can be moved up and down by a driving means (not shown). The support pins 220 receive the wafer W from the robot R of the transfer chamber 110 through holes 221.

Alternatively, the support pins 220 may be fixed on the chamber wall instead of the plate 210. In this case, the plate 210 moves up and down since the support pins 220 are fixed.

A vacuum chuck 230 for holding the wafer W is provided in the plate 210. The vacuum chuck 230 chucks the wafer W to contact a top surface 211 of the plate 210 with the backside 132 of the wafer W. The vacuum chuck 230 extends to a vacuum hole 231 in the plate 210. The vacuum hole 231 is coupled through a vacuum line 232 which is connected to a vacuum pump 234. Also, a vacuum sensor 236 for measuring the vacuum pressure may be disposed in the vacuum line 232.

A nozzle 240 for ejecting gas toward the backside 132 of the wafer W is provided in the plate 210. The nozzle 240 extends to a gas supply hole 241, formed inside the plate 210. The gas supply hole 241 is coupled through a gas line 242 which is connected to a gas supplier 246. A gas valve 244 is installed in the gas line 242 to interrupt the gas supply. Also, a pressure sensor 248 for measuring the gas pressure may be disposed in the gas line 242.

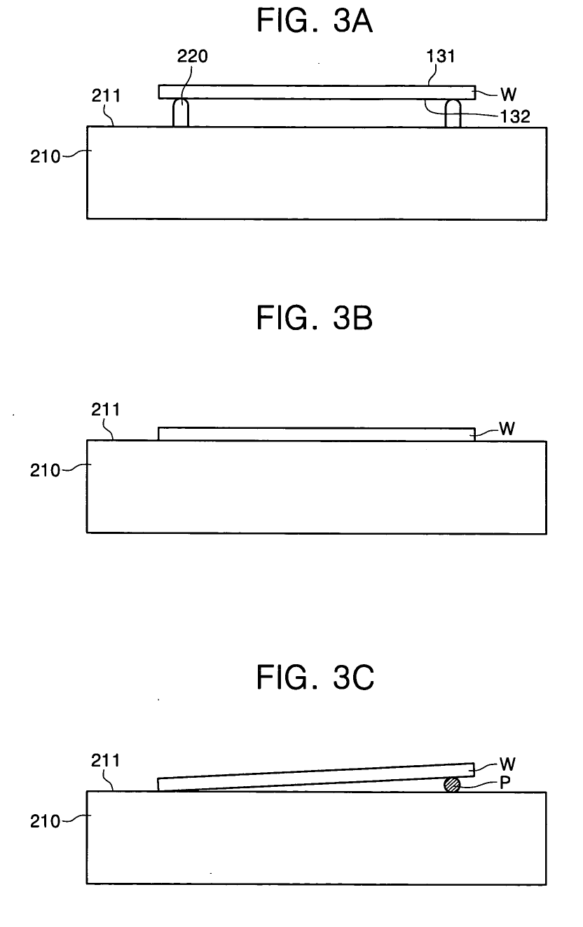

FIGS. 3A to 3B are schematic diagrams illustrating operations of the particle detection chamber 200. Referring to FIG. 3A, when the robot R positions the wafer W on the top of the plate 210 to load the wafer W into the particle detection chamber 200, the support pins 220 move up. Then, the robot R lowers the wafer W onto ends of the support pins 220 and leaves the particle detection chamber 200.

As shown in FIG. 3B, the backside 132 of the wafer W comes in contact with the top surface 211 of the plate 210. After the support pins 220 move down, the vacuum chuck 230 holds the backside 132 of the wafer W as the vacuum pump 234 operates.

As shown in FIG. 3C, the wafer W is displaced due to a particle P. If particles P exist on the backside 132 of the wafer W, the backside 132 does not closely contact the plate 210. The particles P may be by-products generated during previous processes, deposits such as remnants of patterned material, or dust collected during wafer transfer. The particles stick to the backside 132 of the wafer W due to static electricity, etc.

A predetermined vacuum pressure is generated in the vacuum chuck 230 by means of the vacuum pump 234. When the wafer W is displaced due to particles P, the vacuum pressure leaks. The vacuum sensor 236 measures the leakage of the vacuum pressure. If the leakage exceeds a predetermined range, then particles P exist on the backside 132 of the wafer W.

Even if the leakage of the vacuum pressure is within the predetermined range, particles P may exist on the backside 132 of the wafer W. Accordingly, after holding the wafer W by the vacuum chuck 230, the valve 244 is opened to eject gas of a predetermined pressure through the nozzle 240 to the backside 132 of the wafer W. In order for the wafer W to sit properly, the pressure of the gas is set to be smaller than that of the vacuum chuck 230. If particles P exist on the backside 132 of the waver 132, the gas pressure is not uniform. The pressure sensor 248 measures variation in the gas pressure. If the variation is outside of a predetermined range, then particles P exist on the backside 132 of the wafer W.

The gas should not react with various layers, such as insulating layer, etc., formed on the front side 131 of the wafer W. Therefore, it is preferable to use inert gas, which may include at least one among He gas, N₂ gas or Ar gas.

The particle detection chamber 200 detects particles P on the backside 132 of the wafer W in two steps, such as vacuum adhesion and gas ejection. The particle detection chamber 200 detects particles P in advance before transferring the wafer W into the process chamber 160. If detected, as will be described, the contaminated wafer W may be cleaned or discarded. Accordingly, it is possible to reduce contamination of the wafer W and downtime caused by particles P in the process chamber 160.

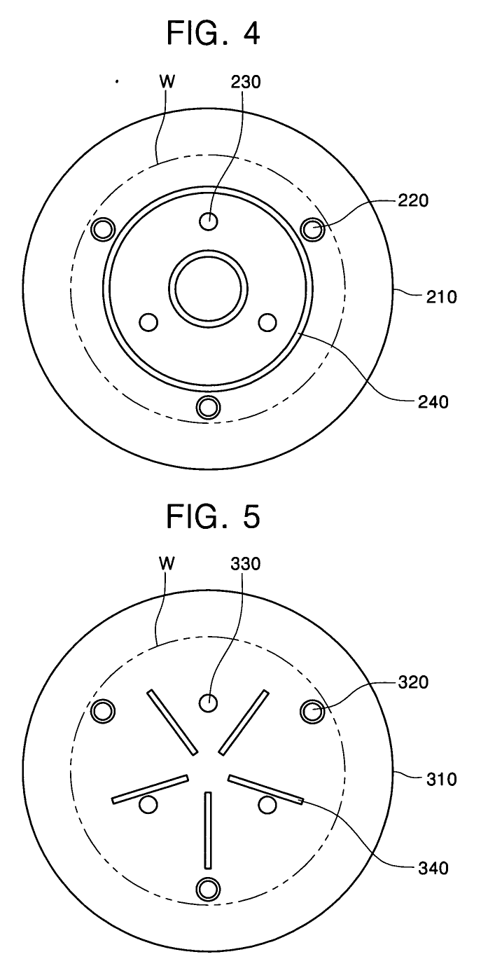

FIG. 4 is a plan view illustrating an example of the particle detection chamber 200. Referring to FIG. 4, the nozzle 240 should be configured to eject gas uniformly toward the backside 132 of the wafer W; otherwise, the system cannot reliably detect particles P due to variation of the pressure caused thereby. Accordingly, the nozzle 240 may be configured in a ring shape to eject gas at a uniform pressure toward the backside 132 of the wafer W.

Alternatively, the nozzle 240 may have another shape as shown in FIG. 5. Referring to FIG. 5, the nozzle 340 may be configured in a slit shape. With the slip shape, a plurality of nozzles 340 may be arranged to eject gas at a uniform pressure toward the backside 132 of the wafer W.

The nozzle can be modified into various forms and is not limited to the examples described above. That is, the nozzle may be formed with a plurality of holes, in a cobweb shape, etc.

Three vacuum chucks 230 and 330 are arranged triangularly in FIGS. 4 and 5, respectively; however this disclosure is not limited to this configuration. To hold the wafer W uniformly, a larger or a smaller number of vacuum chucks may be used.

Referring back to FIG. 1, the wafer cleaning chamber 140 may be connected to the transfer chamber 110. When particles P are detected by the particle detection chamber 130, the contaminated wafer W may be removed to the second load lock chamber 122 through the transfer chamber 110. However, it requires considerable time to clean the removed wafer W and load it into the first load lock chamber 121 again, resulting in process delay.

Accordingly, the wafer cleaning chamber 140 connected to the transfer chamber 110 can readily clean the contaminated wafer W within the apparatus for processing wafers 100. The backside 132 of the wafer W may be cleaned by a dry cleaning process, a semi-dry cleaning process, a wet cleaning process, etc. Wafer cleaning chambers 140 are generally well known in the art.

The aligner 150 may be also disposed on the transfer chamber 110. The aligner 150 aligns the wafer W coarsely. When no particles P are detected on the wafer W in the particle detection chamber 130, or when the particles P are removed via the cleaning process, the robot R of the transfer chamber 110 transfers the wafer W to the aligner 150. After the aligner 150 aligns the wafer W, the robot R introduces the wafer into the process chamber 160.

While the apparatus for processing wafers 100 is described above as including two load lock chambers, one aligner, two process chambers, one wafer cleaning chamber, and one particle detection chamber, this disclosure is not limited to this configuration. The apparatus for processing wafers 100 may include a larger or a smaller number of each element. For example, the apparatus for processing wafers 100 may have five process chambers and two particle detection chambers.

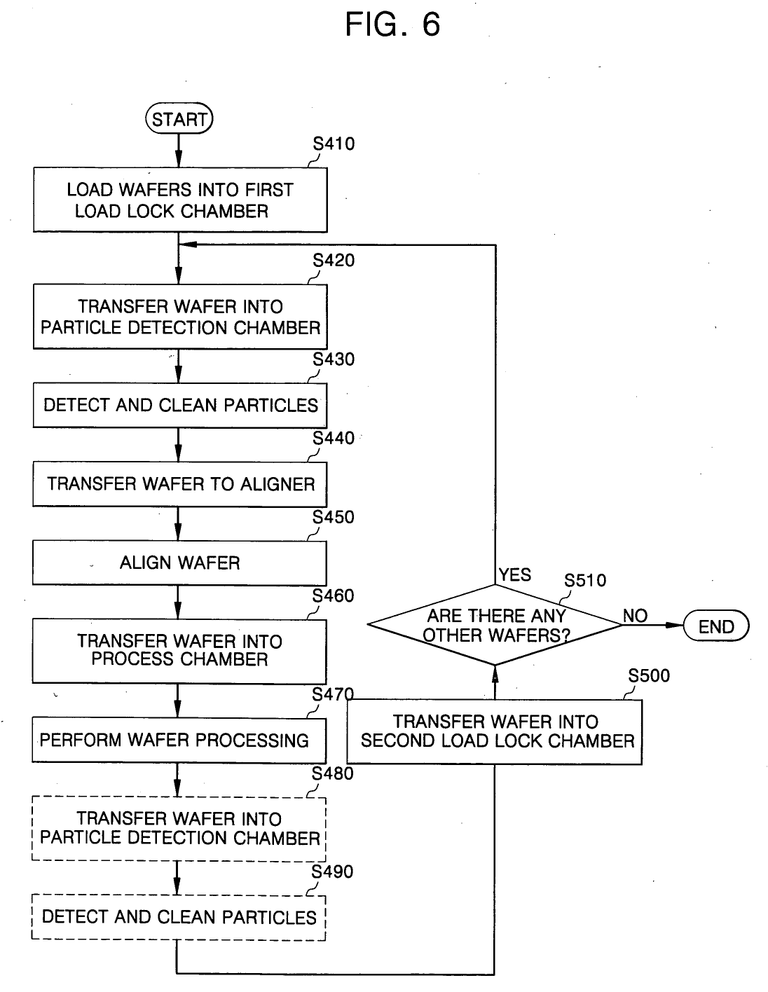

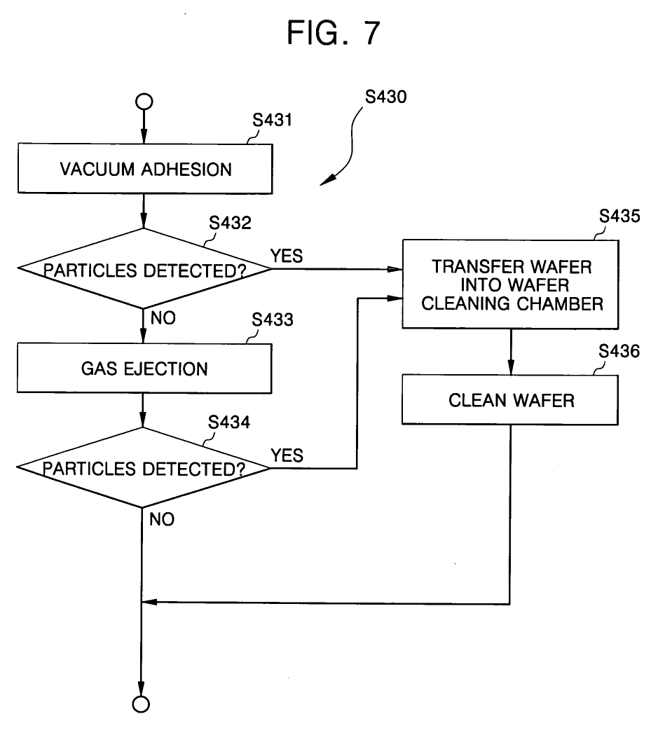

FIG. 6 is a flowchart illustrating the method for processing wafers 400 in accordance with another embodiment of the present general inventive concept. FIG. 7 is a flowchart illustrating step 430 of FIG. 6.

Referring to FIG. 6, a cassette having a plurality of wafers is loaded in the first load lock chamber 121 [S410]. The robot R in the transfer chamber 110 transfers a wafer W from the first load lock chamber 121 into the particle detection chamber 200 [S420].

Particles P on the backside 132 of the wafer W are detected in the particle detection chamber 200 and cleaned from the backside 132 of the wafer W in the wafer cleaning chamber 140 [S430].

Referring to FIG. 7, the vacuum chuck 230 holds the backside 132 of the wafer [S431]. The vacuum sensor 236 measures the vacuum pressure of the vacuum chuck 230 to detect leakage of the vacuum pressure [S432]. If the leakage of the vacuum pressure exceeds a predetermined range, it is determined that particles P exist. If the leakage of the vacuum pressure remains within the predetermined range, gas is ejected at a predetermined pressure from the nozzle 240 toward the backside 132 of the wafer W 240 [S433]. Then, the pressure sensor 248 measures variation in the gas pressure [ST 434]. If the measured variation is outside of a predetermined range, it is determined that particles P exist.

If particles P are detected, the robot R forwards the contaminated wafer W into the wafer cleaning chamber 140 [S435]. Then, the contaminated wafer W is cleaned by a dry cleaning process, a semi-dry cleaning process, or a wet cleaning process in the wafer cleaning chamber 140 [S436].

If no particles P are detected, or if the cleaning process is finished, the robot R conveys the wafer W to the aligner 150 [S440].

Referring back to FIG. 6, the aligner 150 aligns the wafer W [S450]. Then, the robot R introduces the wafer W into the process chamber 160 [S460] and wafer processing is performed in the process chamber 160 [S470].

When the wafer processing is finished, the wafer W may be transferred by the robot R back to the particle detection chamber 130 [S480]. After the wafer processing, the backside 132 of the wafer W may have particles P. Thus, the wafer W is transmitted back to the particle detection chamber 130 for detection. Particles P are detected and cleaned from the backside 132 of the wafer W in the same manner as step S430 [S490]. Accordingly, it is possible to prevent contamination and defects of the wafer W caused by particles P in subsequent processing steps.

The robot R transfers the processed wafer W into the second load lock chamber 122 [S500]. If there is another wafer W waiting to be processed, the robot R moves to the first load lock chamber 121 and repeats step S420 [S510].

The particle detection chamber 200 detects the particles P before transferring the wafer W into the process chamber 160. After performing the wafer processing, the particle detection chamber 200 can also conduct the detection operation. If particles P are detected, the wafer cleaning chamber 140 cleans the backside 132 of the wafer W and subsequent processing steps are followed. Accordingly, it is possible to prevent contamination and defects of the wafer W caused by particles P in subsequent processing steps. Thus, it is possible to reduce downtime caused by particles P in the process chamber 160.

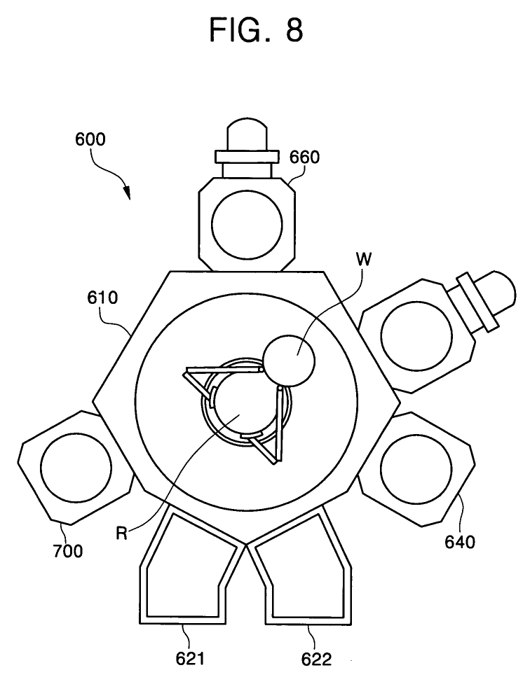

FIG. 8 is a schematic diagram showing an apparatus for processing wafers in accordance with another embodiment.

According to the embodiment of FIG. 8, the aligner and the particle detection chamber are combined to operate at the same time. It is possible to reduce the time required to transfer the wafer by performing both alignment and particle detection in the same chamber.

Aside from the combined aligner and particle detection chamber, all other aspects of the embodiment of FIG. 8 are the same as the embodiment of FIG. 1. Thus, only the aligner which performs both alignment and particle detection will be described.

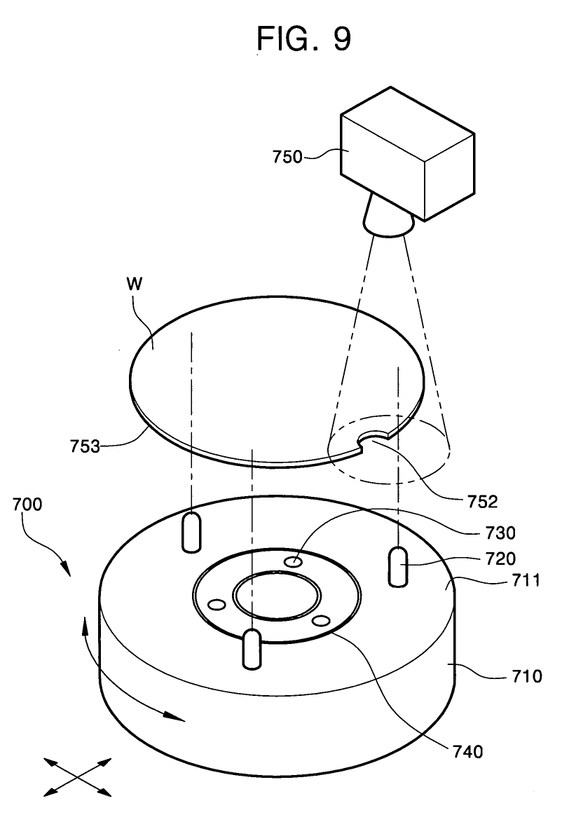

FIG. 9 is a schematic perspective view of the aligner of 700, which performs alignment and particle detection. Referring to FIG. 9, the aligner 700 includes a plate 710 for receiving the wafer W. A chamber wall (not shown) surrounding the plate 710 may be installed to provide an airtight space. Also, the plate 710 can be rotated and moved horizontally by a driving means (not shown).

Support pins 720 onto which the wafer W is temporarily loaded by a robot R are mounted on the plate 710. The support pins 720 can be moved upward and downward by a driving mechanism (not shown). The support pins 720 receive the wafer W from the robot R.

Alternatively, the support pins 720 may be fixed on the chamber wall instead of the plate 710, in which case the plate 710 moves up and down.

A vacuum chuck 730 for holding the wafer W is provided in the plate 710. The vacuum chuck 730 holds the backside 753 of the wafer W in contact with a top surface 711 of the plate 710. A nozzle 740 for ejecting gas toward the backside 753 of the wafer W is provided on the plate 710.

A camera 750 for recognizing a notch 752 or a flat zone is disposed over the wafer W. When the robot R positions the wafer W on the top of the plate 710 to load the wafer W into the aligner 700, the support pins 720 move upward. Then, the robot R lowers the wafer W onto ends of the support pins 720 and leaves the aligner 700. The support pins 720 move downward, and the backside 753 of the wafer W comes into contact with a top surface 711 of the plate 710. Then, the vacuum chucks 730 starts up to hold the backside 753 of the wafer W tightly.

If the wafer W is displaced due to particles, the vacuum pressure leaks. If the vacuum leakage exceeds a predetermined range, it is concluded that particles exist on the backside 753 of the wafer W.

After the vacuum chucks hold the wafer W, gas is ejected at a predetermined pressure from the nozzle 740 toward the backside 753 of the wafer W. If particles exist on the backside 753 of the wafer W, the gas pressure is not uniform. If the variation in gas pressure measured is outside of a predetermined range, it is determined that particles exist on the backside 753 of the wafer W.

If the particles are not detected, the gas supply is suspended.. Then, the camera 750 recognizes the notch 752 of the wafer W. According to the position recognized, the plate 710 is moved to the right or the left, or is rotated to align the wafer W.

A method for processing wafers in accordance with another will now be described with reference to FIGS. 8, 9 and 10.

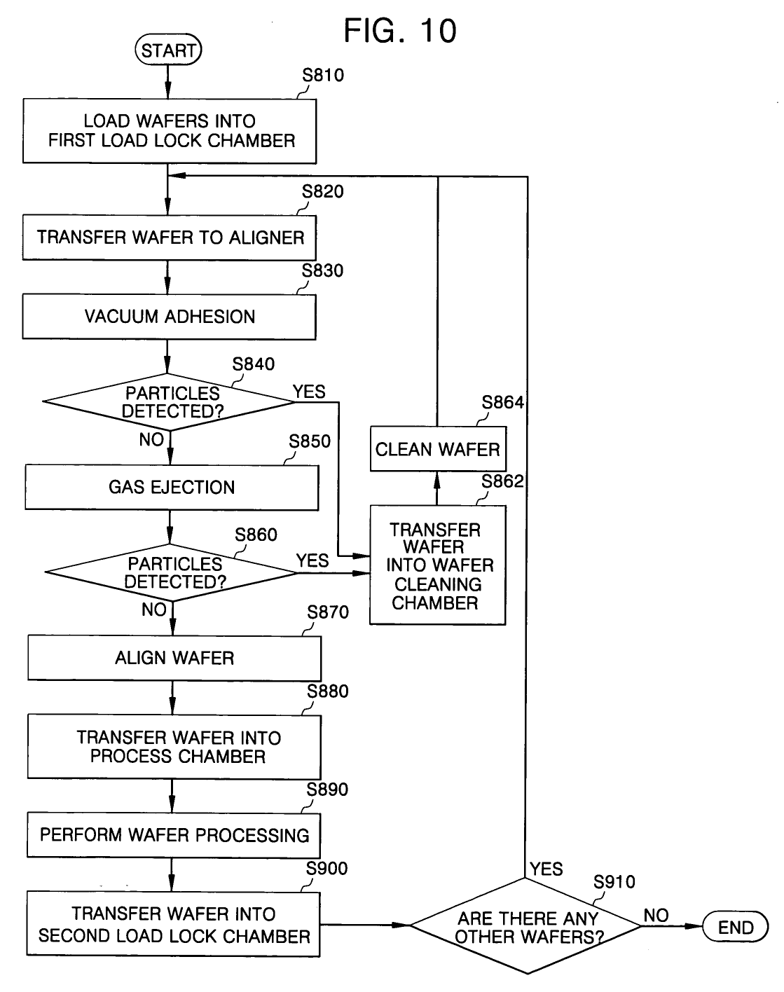

FIG. 10 is a flowchart illustrating a method for processing wafers in accordance with the other embodiment of the present general inventive concept.

Referring to FIG. 10, a cassette receiving a plurality of wafers is loaded in the first load lock chamber 621 [S810]. The robot R in the transfer chamber 610 transfers a wafer W of the first load lock chamber 621 to the aligner 700 [S820].

The backside 753 of the wafer W is sucked into close contact with the top surface 711 of the plate 710 by means of the vacuum chucks 730 [S830]. Leakage of the vacuum pressure is measured [S840]. If the leakage of the vacuum pressure exceeds a predetermined range, it is concluded that particles exist on the backside 753 of the wafer W.

If particles are not detected, the nozzle 740 ejects gas at a predetermined pressure toward the backside 753 of the wafer W [S850]. Then variation of the gas pressure is measured [S860]. If the measured variation is outside of a predetermined range, it is determined that particles exist.

If particles are detected, the robot R forwards the wafer W into the wafer cleaning chamber 640 [S862]. Subsequently, the wafer W is cleaned by a dry cleaning process, a semi-dry cleaning process, or a wet cleaning process in the wafer cleaning chamber 640 [S864]. If the wafer cleaning process is finished, the robot R transfers the wafer W to the aligner 700.

If no particles are detected, the wafer W is aligned [S870]. Then, the robot R conveys the aligned wafer W into the process chamber 660 [S880] and the wafer processing is conducted in the process chamber [S890]. When the wafer processing is finished, the robot R transfers the processed wafer W into the second load lock chamber [S900]. If there is another wafer W waiting to be processed, the robot R moves to the first load lock chamber 621 [S910].

In the embodiments described above in detail, the presence of particles on the backside of the wafer is detected before the wafer is introduced into the process chamber. Accordingly, it is possible to reduce contamination and defects caused by the particles in the process chamber. Consequently, it is possible to perform reliable wafer processing without loss in productivity.

While this general inventive concept has been described in terms of several preferred embodiments, there are alternations, permutations, and equivalents, which fall within the scope of this invention. It should also be noted that there are many alternative ways of implementing the methods and apparatuses of the present general inventive concept. It is therefore intended that the following appended claims be interpreted as including all such alternations, permutations, and equivalents as fall within the true spirit and scope of the present disclosure.

1. A method of processing wafers comprising:
detecting the presence of a particle on a backside of a wafer, while holding the wafer with a vacuum pressure;
transferring the wafer into a process chamber; and
performing a wafer processing in the process chamber.

2. The method of claim 1, wherein detecting the presence of a particle on a backside of the wafer includes detecting when the vacuum pressure is outside of a predetermined range.

3. The method of claim 1, wherein detecting the presence of a particle on a backside of the wafer includes ejecting a gas toward a backside of the wafer and measuring a variation of pressure of the ejected gas.

4. The method of claim 3, wherein the ejected gas is selected from the group consisting of helium, nitrogen, argon and combinations thereof.

5. The method of claim 1, further comprising cleaning the wafer if a particle is detected on the backside of the wafer after detecting the presence of a particle.

6. The of claim 1, further comprising detecting the presence of a particle on the backside of the wafer while holding the wafer with a vacuum pressure after performing the wafer processing in the process chamber.

7. The method of claim 6, further comprising cleaning the wafer if a particle is detected after detecting the presence of a particle on the backside of the wafer after performing the wafer processing.

8. A method for processing wafers comprising:
loading a wafer into a transfer chamber;
transferring the wafer to an aligner connected to the transfer chamber;
holding the wafer with a vacuum pressure in the aligner;
detecting the presence of a particle on a backside of the wafer in the aligner;
transferring the wafer into a process chamber connected to the transfer chamber; and
performing a wafer processing in the process chamber.

9. The method of claim 8, wherein detecting the presence of a particle on the backside of the wafer in the aligner includes detecting when the vacuum pressure is outside of a predetermined range.

10. The method of claim 8, wherein detecting the presence of a particle on the backside of the wafer in the aligner includes ejecting a gas toward the backside of the wafer and measuring a variation of pressure of the ejected gas.

11. The method of claim 10, wherein the ejected gas is selected from the group consisting of helium, nitrogen, argon and combinations thereof.

12. The method of claim 8, further comprising cleaning the wafer if a particle is detected after detecting the presence of a particle.

13. The method of claim 8, further comprising aligning the wafer if no particle is detected.

14. A wafer processing apparatus comprising:
a transfer chamber;
a load lock chamber connected to the transfer chamber;
a process chamber connected to the transfer chamber; and
a particle detection chamber connected to the transfer chamber, wherein the particle detection chamber includes a wafer receiving plate and a vacuum chuck disposed in the wafer receiving plate to hold the wafer in contact with the plate.

15. The apparatus of claim 14, further comprising a cleaning chamber connected to the transfer chamber.

16. The apparatus of claim 14, wherein the particle detection chamber includes a nozzle in the wafer receiving plate to eject gas toward a backside of the wafer.

17. The apparatus of claim 16, wherein the nozzle is configured in a ring shape.

18. The apparatus of claim 16, wherein the nozzle is configured in a slit shape.

19. A method of detecting a particle on a backside of a wafer comprising:
holding the wafer with a vacuum pressure; and
detecting the presence of a particle on the backside of the wafer by measuring a gas pressure.

20. The method of claim 19, wherein detecting the presence of a particle on the backside of the wafer by measuring a gas pressure includes measuring the vacuum pressure.

21. The method of claim 19, wherein detecting the presence of a particle on the backside of the wafer by measuring a gas pressure includes ejecting a gas toward the backside of the wafer and measuring a variation of pressure of the ejected gas.

22. The method of claim 21, wherein ejecting a gas toward the backside of the wafer includes ejecting the gas through a ring-shaped nozzle.

23. The method of claim 21, wherein ejecting a gas toward the backside of the wafer includes ejecting the gas through a slit-shaped nozzle.
